(19) United States
(12) Patent Application Publication
(10) Pub. No.: US 2005/0269671 A1
(43) Pub. Date: Dec. 8, 2005

(54) Support for hybrid epitaxy and method of fabrication

(76) Inventors: Bruce Faure, Grenoble (FR); Hacene Lahreche, Paris (FR)

Correspondence Address: WINSTON & STRAWN LLP, 1700 K STREET, N.W., WASHINGTON, DC, 20006, US

(21) Appl. No.: 10/915,765

(22) Filed: Aug. 10, 2004

(30) Foreign Application Priority Data
Jun. 3, 2004 (FR) 0405992

(51) Int. Cl. H01L 23/12; H01L 29/20; H01L 21/58

(52) U.S. Cl. 257/618; 428/698; 428/446; 257/701; 438/458; 438/478

(57) ABSTRACT

A method for producing a support for epitaxy by forming a layer of insulating monocrystalline silicon carbide or insulating monocrystalline gallium nitride in a first substrate of conducting monocrystalline silicon carbide or gallium nitride. The method also includes transfer of the monocrystalline layer of silicon carbide or gallium nitride onto a second substrate formed from a polycrystalline ceramic material having thermal conductivity of 1.5 W.cm⁻¹.K⁻¹ or more. This method enables high performance electronic components to be produced cheaply, in particular for high frequency power applications.

### FIELD OF THE INVENTION AND BACKGROUND ART

The invention relates to the field of techniques for epitaxy, in particular for the production of layers of materials such as gallium nitride (GaN), aluminum nitride (AlN), indium nitride (InN), or their compounds.

It also relates to the field of radio frequency (RF) and microwave circuits based on materials such as GaN, AlN and their compounds.

As yet, there is still no method for pulling an ingot to produce monocrystalline substrates of GaN or other nitrides that is similar to the method of pulling silicon. Such materials are primarily obtained by forming a thin film by hetero-epitaxy on substrates that are essentially formed from sapphire (Al₂O₃), but are also in some cases formed from silicon carbide (SiC) or silicon (Si). Although nitrides are usually used in the form of a thin film, it is also possible to find monocrystalline GaN in the form of a bulk material. Such substrates are obtained by hetero-epitaxy of a thick layer of GaN (typically the thickness of the substrate) on a substrate of a different nature, such as (111) gallium arsenide (GaAs) with a particular surface patterning, which substrate is subsequently removed following epitaxy, as described in U.S. Pat. No. 6,413,627. This approach can produce relatively high quality substrates, albeit in small quantities (non industrial) and at a relatively high cost.

A great deal of highly active research and development has been carried out on wide bandgap nitride type materials (GaN, AlN, InN and compounds thereof). Such materials have a fairly wide range of applications. One important property of such materials is their large direct bandgap, which makes them emitters of blue light or of violet and ultraviolet light when compounded with other species (for example gallium-indium nitride (InGaN)) and when used in suitable component structures (laser UV, blue LED, white LED, etc). Because of their wide direct bandgap property, materials from the nitride family (such as GaN, AlN, InN etc) can be used in a large number of optoelectronics applications. However, those wide bandgap properties endow that family of materials with other highly advantageous properties, for example in high frequency power applications.

Of these materials, the characteristics of GaN, such as its energy gap, breakdown field, and charge carrier saturation rate, are very advantageous as regards high frequency power applications.

SiC also has very advantageous properties, the main advantage of SiC over GaN being its thermal conductivity, which is more than 4 times higher than that of GaN. Such a criterion is important for the operation of power components, since as much as possible of the natural heating generated by the component must be evacuated so that it does not influence its operation.

Nitrides, and in particular GaN and its compounds, are obtained by hetero-epitaxy on a foreign material. The principal materials used as a substrate or support for thin film epitaxy are sapphire (Al₂O₃), silicon carbide (SiC) and (111) silicon (Si). These three materials are used, for example, to produce single layers of GaN or more complex stacks of hetero-structures and superstructures for electroluminescent diodes, lasers, RF and microwave components, etc.

Silicon is highly advantageous because it is easy to obtain, it is inexpensive, and skills regarding micro-fabrication technologies using this material have been well honed. However, the quality of GaN layers obtained on (111) Si suffers from differences in the lattice parameter and in the thermal expansion coefficient between silicon and GaN.

Like silicon, SiC has a thermal expansion coefficient that is lower than that of GaN. Thus, a film of GaN grown epitaxially on silicon carbide will be under tension when the temperature is reduced after the high temperature epitaxial growth step. However, that effect is more marked on silicon since the difference in the thermal expansion coefficient is greater between Si and GaN than between SiC and GaN. The number of defects in a layer of GaN which is under tension thus tends to increase on silicon and it can even crack during cooling. For this reason, but also because of the hexagonal crystalline structure of SiC and its lattice parameter, which is close to that of GaN, better quality layers are obtained on SiC than on silicon.

Sapphire can produce good quality epitaxially grown layers since, in contrast to silicon and SiC, its thermal expansion coefficient is higher than that of GaN, which means that the epitaxially grown GaN layer can be kept under compression when the temperature drops following epitaxy. This compressive state is the best means of limiting the appearance of defects in the GaN layer, in particular cracking of the film, as happens with SiC. Since that possible cracking is linked to a limiting thickness of GaN, using sapphire means that thicker layers can be produced without cracking or the appearance of defects. Making the layer thicker means that the number of defects induced by differences in the lattice parameters of the epitaxially grown layer and the substrate can be partially reduced (by annihilation between defects). Thus, epitaxial layers can be grown on sapphire with the same crystalline quality as on Sic.

Currently, most hetero-epitaxial GaN is grown on SiC or sapphire substrates regardless of the intended application. A large number of advanced epitaxy techniques, such as the use of a buffer layer of greater or lesser complexity, epitaxial lateral overgrowth, or pendeoepitaxy, can produce layers with fewer and fewer defects and components of ever increasing complexity and performance, quantum super-lattice lasers, or high electron mobility transistors (HEMT).

The technique which produces the best GaN layers is clearly homo-epitaxy, i.e., growing GaN epitaxially on a GaN substrate. Such GaN substrates are currently also obtained by hetero-epitaxy and many crystalline defects are present in such substrates. Nevertheless, their density is substantially lower than that of a thin film obtained by hetero-epitaxy (100 to 1000 times fewer dislocations, for example). This can produce layers of excellent quality but with certain limitations, such as the size of the substrates produced, which is currently below 50.8 mm (2 inches), or their availability on the market is too low to ensure a sufficient supply. Further, in contrast to SiC substrates, the GaN substrates which are available are solely of the conductor type.

Technically speaking, it has been possible to produce all sorts of components both on (111) silicon and on sapphire or SiC. However, two criteria must be taken into account if the epitaxially grown structure obtained is to be used for high frequency power applications:
heat evacuation ensured by the substrate to limit self-heating of the component and to ensure that it operates in a stable manner and performs well; and
the insulating character of the circuit support, to allow the production of passive components (capacitor, inductor, etc) and transmission lines (electrical waveguide) with good characterization and minimal signal loss.

Sapphire is a natural insulator and, as already described above, can produce good quality layers of GaN and its compounds, but its thermal conductivity limits heat evacuation.

The thermal conductivity of SiC is more than 10 times higher than that of sapphire and thus ensures very good evacuation of heat for high frequency power components based on GaN. Further, epitaxial techniques now exist for producing layers with a minimum number of defects.

However, SiC is seldom used because of its very high cost. As an example, for hetero-epitaxy treatments, compared with the cost of a sapphire structure, an SiC substrate costs between 10 times more for conducting wafers and 50 times more for semi-insulating wafers. The extra costs involved with the use of SiC limits the use of that type of substrate to high frequency power applications.

Further, bulk GaN substrates still suffer from too many disadvantages to constitute an industrial solution. Such substrates have poorer thermal properties than SiC; in particular, their thermal conductivity is of the same order as that of Si. Further, the dimensions of the little GaN which is available on the market are too small for industrial applications and it is still very expensive (one to two times the price of a SiC substrate). Finally, there is currently no semi-insulating GaN in the form of a substrate; it only exists in the form of an epitaxially grown thin film.

The current state of technology thus imposes a choice between high performance components at a very high cost (on SiC) and lower performance components at a lower cost (on sapphire or on silicon).

Thus, there is a problem with finding alternative techniques for epitaxy and corresponding substrates or supports that can allow high performance electronic components to be produced at a reasonable cost, in particular components based on nitride materials such as GaN, AlN or InN or compounds thereof.

The present invention now provides solutions to the limitations of the prior state of the art.

### SUMMARY OF THE INVENTION

According to the invention, a support for hybrid epitaxy is produced, composed of a thin layer of a semi-insulating or insulating material, preferably of SiC or GaN, on a support of a polycrystalline material having high thermal conductivity.

Thus, one implementation of a method in accordance with the invention comprises:
forming a layer of insulating monocrystalline SiC or GaN in a first substrate of conducting monocrystalline SiC or GaN; and
transferring said layer of monocrystalline SiC or GaN onto a second substrate formed from polycrystalline ceramic material having thermal conductivity of 1.5 watts per centimeter per kelvin (W.cm⁻¹.K⁻¹) or more.

Thus, the cost of producing a support for epitaxy is significantly reduced by forming a layer of monocrystalline SiC in a substrate of conducting SiC. In fact, the cost of a conducting SiC substrate is 5 times lower than that of a semi-insulating SiC substrate.

Further, in the case of GaN, forming a semi-insulating layer of GaN in a conducting GaN substrate can produce GaN substrates with electrical conductivity that is compatible with high frequency power applications, which is impossible with GaN as currently available in bulk form.

The invention also relates to a support structure of the type obtainable by the method and to an electronic structure comprising the support and at least one layer of a nitride material in which at least one electronic component is formed.

Another embodiment of the invention relates to a method for facilitating epitaxial growth of a layer of a nitride material, which comprises providing a layer of an insulating monocrystalline carbide or nitride on a substrate formed from a polycrystalline ceramic material having thermal conductivity of at least 1.5 W.cm⁻¹.K⁻¹ so that the nitride layer can be epitaxially grown thereon. If desired, an active conducting layer can be formed on the epitaxially grown layer, and the active layer can be etched or otherwise processed to form at least one electronic component, such as an inductor, capacitor, transmission line, or transistor.

### BRIEF DESCRIPTION OF THE DRAWING FIGURES

FIGS. 1A to 1F show steps in a method in accordance with the invention;

FIGS. 2A and 2B show steps for epitaxy and production of insulating structures using a substrate for epitaxy of the invention;

FIG. 3 is an example of an HEMT structure based on GaN and AlGaN.

### DETAILED DESCRIPTION OF THE PREFERRED EMBODIMENTS

In a particular implementation, the layer of monocrystalline SiC or GaN can preferably be produced by ion implantation of hydrogen or a rare gas such as helium or argon, or a hydrogen/rare gas combination (co-implantation) into the first conducting monocrystalline SiC or conducting monocrystalline GaN substrate. This implementation has the advantage that the initially conducting SiC or GaN becomes insulating or semi-insulating after implantation, regardless of the SiC polytype used initially for the first substrate. This property of high resistivity of the film after transfer by implantation followed by high temperature annealing persists even after annealing for several hours at 1300° C. This high resistivity of the transferred thin film will thus be conserved after epitaxy of a nitride (GaN, AlN, InN or compounds thereof).

The second substrate onto which the insulating monocrystalline SiC layer is transferred can be a polycrystalline SiC having electrical resistivity of at least 10⁴ ohmcentimeters (Ω.cm) or a substrate of polycrystalline AlN which is insulating or has electrical resistivity of at least 10⁴ Ω.cm.

Polycrystalline SiC has the same thermal expansion and thermal conductivity properties as monocrystalline SiC, and it can be obtained in a semi-insulating form with resistivity of 10⁴ Ω.cm or more, for example in the range 10⁴ Ω.cm to 10⁵ Ω.cm. Thus, polycrystalline SiC can be used to produce supports for RF and microwave circuits which have electrical and thermal properties equivalent to those obtained with monocrystalline SiC, but at a much lower cost.

Non-destructive separation of a portion of the first substrate from the monocrystalline SiC layer allows recycling or re-use of this portion of the first substrate, for example to produce other supports for epitaxy.

Transfer of a layer of monocrystalline SiC onto a polycrystalline SiC support can be carried out directly without any intermediate layer, or it can be carried out via an insulating layer which may be silicon oxide or silicon nitride, or other insulating materials with good thermal conductivity.

Silicon nitride is particularly suitable for this type of application as it has a relatively high thermal conductivity of 0.3 W.cm⁻¹.K⁻¹, which is much higher than that of silicon oxide. Further, the thickness of the intermediate insulating layer can be minimized (for example in the range 50 nanometers (nm) to 500 nm) so that it has a very small influence on heat evacuation, which is primarily ensured by the polycrystalline SiC support (which can be several hundred micrometers (μm) thick).

The monocrystalline SiC layer can be transferred by fracturing the first substrate, for example along a layer or a plane of weakness, and preferably at a temperature in the range 300° C. to 1100° C. The step for transferring the monocrystalline SiC layer onto the second substrate can be carried out by assembling the two substrates by molecular bonding; it can be preceded by a chemical or chemical-mechanical cleaning step, and it can be followed by an annealing step at a temperature in the range 900° C. to 1200° C.

The invention also provides a support for epitaxy comprising a substrate of polycrystalline material having a thermal conductivity of 1.5 W.cm⁻¹.K⁻¹ or more and a layer for epitaxial growth formed from insulating monocrystalline SiC or GaN. The substrate can be a substrate formed from insulating polycrystalline SiC or a polycrystalline AlN substrate that can be insulating or have electrical resistivity of at least 10⁴ Ω.cm. The substrate can also be formed with other ceramic materials with a thermal conductivity of 1.5 W.cm⁻¹.K⁻¹ or more and electrical resistivity of at least 10⁴ Ω.cm.

In accordance with one feature of the invention, the support for epitaxy further comprises an insulating layer between the polycrystalline substrate and the layer of monocrystalline silicon carbide which may be silicon oxide or silicon nitride. The thickness of the insulating layer can be in the range 10 nm to 3 μm.

The invention also provides an electronic structure comprising a support for epitaxy as described above and at least one layer of a nitride material in which at least one electronic component has been produced. The nitride material can be gallium nitride (GaN), aluminum nitride (AlN), indium nitride (InN), gallium-indium nitride (InGaN), or a compound of gallium nitride and aluminum nitride. This layer of nitride material is preferably obtained by epitaxial growth carried out on the previously described support for epitaxy.

In accordance with a particularly preferred embodiment, an active conducting layer is also formed on at least a portion of the nitride layer. This active layer can then be etched to form one or more electronic components such as an inductor and/or a capacitor and/or a transmission line and/or a transistor.

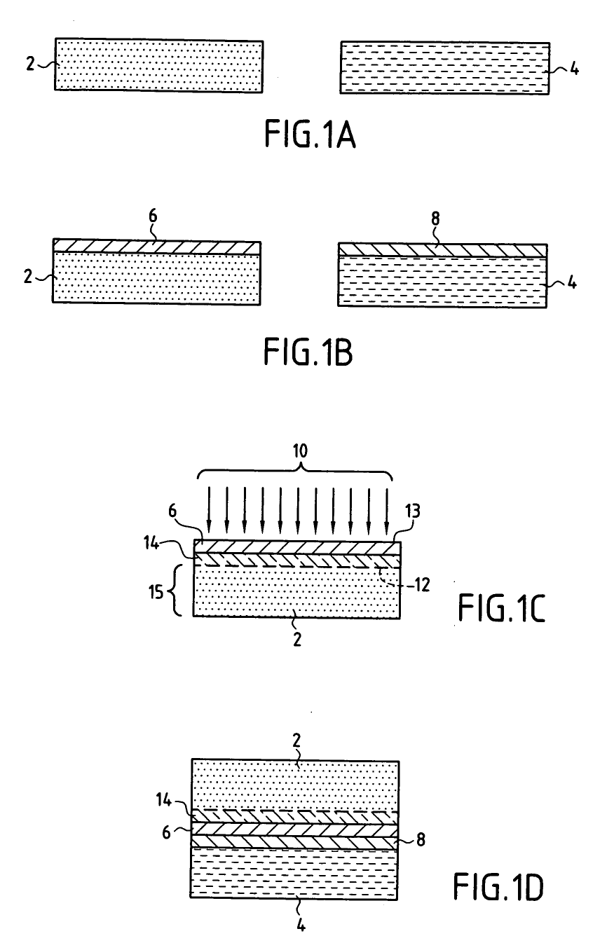

The steps of a method in accordance with the invention are shown in FIGS. 1A to 1F.

In the example considered here, a first substrate 2 (FIG. 1A) is formed from standard conducting monocrystalline silicon carbide SiC with polytype 6H, 4H or 3C. However, in accordance with the invention, the first substrate 2 can also be formed from conducting monocrystalline gallium nitride GaN. In this case, the steps in the method described below regarding a monocrystalline SiC substrate are carried out with a monocrystalline GaN substrate in place of the SiC substrate, the GaN substrate being a bulk GaN substrate or a GaN substrate obtained by epitaxy on another substrate followed by hydrogen implantation.

A second substrate 4 is formed from insulating polycrystalline silicon carbide SiC (typically with a resistivity of 10⁴ Ω.cm or more). In accordance with a variation of the invention, the second substrate 4 can also be formed from polycrystalline aluminum nitride (AlN).

During the next step (FIG. 1B), layers 6, 8 of insulating material, for example of silicon oxide or silicon nitride type, are deposited or grown. Other materials can be used if they are insulators and have good thermal conductivity (silicon oxynitride, for example). The thickness of these layers can be from 10 nm or several tens of nanometers to 1 μm or more than one micrometer, and for example is most preferably about 3 μm. It is possible to use both layers 6, 8 or only one of them, as desired. The layers can be of the same or of different natures or materials.

Atom or ion implantation 10 is carried out in substrate 2 (FIG. 1C) through layer 6 to form a thin layer 12 which extends substantially parallel to a surface 13 of the substrate 2, to form a layer or a plane of weakness or fracture defining a region 6, 14 in the volume of the substrate 2, intended to constitute a thin film, and a region 15 constituting the mass of the substrate 2. Said implantation is generally hydrogen implantation, for example at a dose in the range 1×10¹⁶ to 1×10¹⁷H⁻/cm² with energy in the range 20 kiloelectronvolts (keV) to 200 keV. Implantation can also be carried out using other species, or with H/He co-implantation.

A buried layer 12 of defects created by implantation is thus obtained. This layer separates the substrate 2 from a layer 14 of monocrystalline SiC with a thickness in the range of about 10 nm to 1 μm, rendered semi-insulating by ion implantation.

Prior to assembling the substrates, different methods may be used to prepare their surfaces for bonding, such as: CARO or RCA (SC1, SC2) type chemical cleaning, “UV-ozone” cleaning, plasma surface activation, chemical-mechanical polishing of layers 6 and 8, or chemical-mechanical scrubber type cleaning, or a combination of these different methods to obtain optimum bonding.

In accordance with variations of the invention, the layer 6 and/or the layer 8 can be removed prior to bonding to obtain bonding by molecular bonding in all envisagable configurations and in particular to provide the possibility of direct bonding between the surfaces of the layer 14 and the substrate 4.

The two substrates are then assembled (FIG. 1D) and a transfer anneal is carried out at a temperature in the range 300° C. to 1100° C. for a period of a few minutes to several hours depending on the temperature. One example of a thermal transfer method could be to anneal for 1 hour at 900° C., optionally combined with supplying mechanical energy. This results in separation along the plane of weakness formed by the ion layer 12.

More precisely, the two substrates 2 and 4 are assembled by a wafer bonding type technique or by adhesive contact, for example by molecular bonding or adhesion. Reference regarding these techniques should be made to the work by Q. Y. Tong and U. Gosele, “Semiconductor Wafer Bonding” (Science and Technology), Wiley Interscience Publications.

A portion of the substrate 2 is then detached by a treatment that can cause a fracture along the plane of weakness 12. One example of this technique is described in the article by A. J. Auberton-Hervé et al, entitled “Why can SMART-CUT change the future of microelectronics?” published in the International Journal of High Speed Electronics and Systems, Vol 10, no. 1 (2000), p 131-146.

The structure 16 (FIG. 1E) is thus obtained, which structure is entirely insulating (insulating substrate 4 and insulating layers 6 and 14). None of the subsequent steps will change this property.

A high temperature annealing step (between 900° C. and 1200° C.) can then be employed to strengthen the bonding interface or cause it to disappear to avoid any subsequent risk of delamination of the film 14. Sacrificial oxidation or a chemical-mechanical polishing step or a combination of these two techniques can be employed to reduce the roughness of the surface 18, in order to carry out future epitaxial growth steps under the best possible conditions. The roughness of the surface 18 can also be reduced by a dry plasma etching step, by an ion beam etching step or by annealing operations in a non-oxidizing atmosphere.

It is then possible to recycle the monocrystalline SiC substrate 2 (FIG. 1F), for example after chemical-mechanical polishing and chemical cleaning, to re-use it for the same type of application. Such recycling can substantially reduce the final cost of the structure 16.

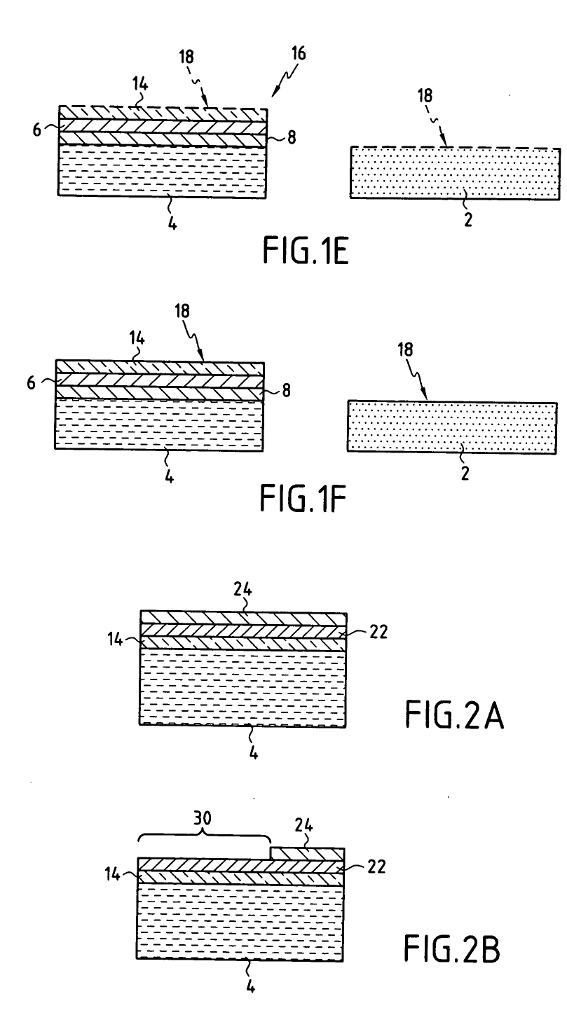

An epitaxial layer 22 can then be produced (FIG. 2A), for example of GaN or any other material, in particular of the nitride type (InN, AlN, or a compound of GaN and AlN), to produce the final components. The epitaxy technique used is MOCVD, MBE or HVPE, for example.

It is also possible to produce complex structures, for example of the type comprising quantum wells or high mobility electron gases.

Preferably, the epitaxy temperature does not exceed 1300° C. for several hours, in order to preserve the insulating nature of the SiC layer 14. This temperature is in the range 700° C. to 1200° C., for example. In one example, to produce a high frequency power circuit, a layer of semi-insulating GaN 22 is initially grown epitaxially, followed by an active conducting layer 24 comprising a gas of high mobility electrons to subsequently produce a HEMT transistor.

The final circuit can be fabricated (FIG. 2B) by removing the active layer by wet or dry etching in zones 30 in which passive components (inductor, capacitor, transmission lines etc) are to be produced. In the regions 30 in which the conducting layer 24 is removed, there remains only a completely insulating structure having very good heat evacuation properties, which means that very good quality performances can be obtained for the circuit that is produced, even at high frequencies and high power.

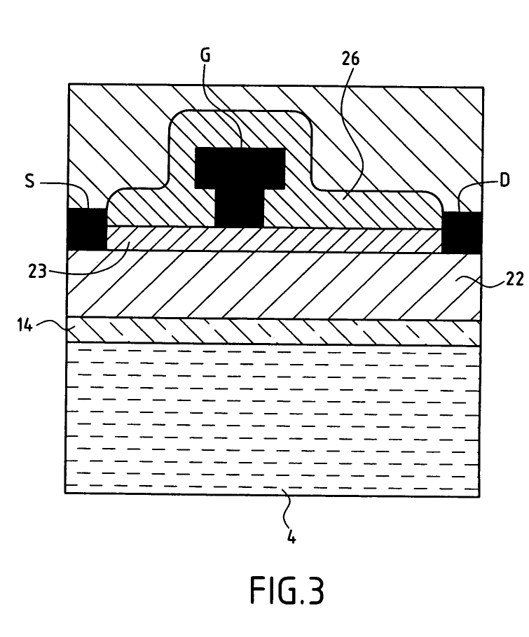

FIG. 3 shows a cross-section of a HEMT structure, comprising a SiC substrate, provided with a layer 14 of monocrystalline insulating SiC obtained in accordance with the invention, and an epitaxially grown structure comprising a layer 22 of GaN and a layer 23 of AlGaN. The layer 26 is a passivation layer. Reference letters S, D and G respectively designate the source, drain, and grid of the transistor obtained.

Table 1 below compares the proposed structure with semi-insulating SiC and sapphire.

TABLE 1
Comparison between proposed structure and other
substrates employed

| | SiC in | | | | |
|---|---|---|---|---|---|
| | accordance | | | | |
| | with the | | | Semi- | |
| | invention | | | insu- | |
| | (high dose | SiO₂ | Poly | lating | |
| | implanted H+) | Si₃N₄ | SiC | SiC | Sapphire |
| Thermal | 2.8 | 0.014 | 2.8 | 2.8 | 0.23-0.5 |
| conductivity | | 0.15-0.30 | | | |
| (W.cm⁻¹.K⁻¹) | | | | | |
| Resistivity | >10⁵ | insulating | >10⁴ | ˜10⁵ | insulating |
| (Ω.cm) | (T < 1300° C.) | | | | |

It can be seen that the proposed structure of the invention (insulating monocrystalline SiC layer on polycrystalline SiC or AlN substrate) will have thermal characteristics (heat evacuation) and electrical characteristics (insulating character of the structure) comparable to semi-insulating SiC, but at a much lower cost (about 3 times less than with a semi-insulating monocrystalline SiC substrate), in particular because of the possibility of recycling the monocrystalline SiC substrate 2 which represents the major portion of the total cost of the structure.

Further, when using conducting monocrystalline GaN as the starting substrate, it is possible to form structures such as those described above with a layer of semi-insulating GaN in the form of a substrate, the semi-insulating GaN until now only being obtainable by epitaxy in the form of a thin film that is difficult to transfer from one support to another (i.e., on a polycrystalline SiC or AlN substrate).

Furthermore, the structure of the invention is completely compatible with GaN epitaxy, to the same degree as semi-insulating monocrystalline SiC. Its properties, in particular its insulating nature, are not modified during epitaxy. The method of the invention employed to produce a monocrystalline SiC/polycrystalline SiC structure, a monocrystalline SiC/insulator/polycrystalline SiC structure, a monocrystalline SiC/polycrystalline AlN structure, a monocrystalline SiC/insulator/polycrystalline AlN structure, a monocrystalline GaN/polycrystalline SiC structure, a monocrystalline GaN/insulator/polycrystalline SiC structure, a monocrystalline GaN/polycrystalline AlN structure or a monocrystalline GaN/insulator/polycrystalline AlN structure thus offers an alternative to using substrates of semi-insulating monocrystalline SiC or monocrystalline conducting GaN for epitaxy, particularly of a nitride, for high frequency power applications.

1. A method for producing a support for epitaxy, which comprises:
forming a layer of an insulating monocrystalline carbide or nitride in a first substrate of a conductive carbide or nitride; and
transferring the layer onto a second substrate formed from a polycrystalline ceramic material having thermal conductivity of at least 1.5 W.cm⁻¹.K⁻¹.

2. The method of claim 1, wherein the carbide is silicon carbide or the nitride is gallium nitride

3. The method of claim 1, wherein the insulating monocrystalline layer is defined by implanting ions into the first substrate.

4. The method of claim 3, wherein the ions are hydrogen, a rare gas ion, or a combination of hydrogen and a rare gas ion.

5. The method of claim 1, wherein the second substrate is a polycrystalline silicon carbide substrate having electrical resistivity of at least 10⁴ Ω.cm.

6. The method of claim 1 wherein the second substrate is a substrate of polycrystalline aluminum nitride which is insulating or has electrical resistivity of at least 10⁴ Ω.cm.

7. The method of claim 1, wherein the layer of monocrystalline carbide or nitride has resistivity in the range 10⁴ Ω.cm to 10⁵ Ω.cm.

8. The method of claim 1, which further comprises providing a further layer of an insulating material on at least one of the first and second substrates.

9. The method of claim 8, wherein each layer of insulating material has thickness in the range of about 10 nm to 3 μm.

10. The method of claim 1, wherein the layer is transferred to the second substrate by fracturing the first substrate along a plane of weakness constituted by the implanted ions.

11. The method of claim 10, wherein the first substrate is fractured at a temperature in the range of 300° C. to 1100° C.

12. The method of claim 1, which further comprises joining the two substrates by molecular bonding prior to transferring the layer to the second substrate.

13. The method of claim 1, which further comprises conducting one or more cleaning steps selected from the group consisting of chemical cleaning, chemical-mechanical cleaning, “UV-ozone” cleaning, and plasma surface activation, on the first or second substrates, or both, prior to transferring the layer to the second substrate.

14. The method of claim 1, which further comprises conducting an annealing step at a temperature in the range of 900° C. to 1200° C. after transferring the layer to the second substrate.

15. A support for epitaxy, comprising:
a substrate formed from a polycrystalline material having a thermal conductivity of 1.5 W.cm⁻¹.K⁻¹ or more; and
a layer for facilitating epitaxial growth thereon, the layer formed from an insulating monocrystalline carbide or nitride.

16. The support of claim 15, wherein the carbide is silicon carbide or the nitride is gallium nitride

17. The support of claim 15, wherein the substrate is formed from polycrystalline silicon carbide.

18. The support of claim 15, wherein the substrate is formed from polycrystalline aluminum nitride.

19. The support of claim 15, further comprising an insulating layer between the polycrystalline substrate and the carbide or nitride layer.

20. The support of claim 18, wherein the insulating layer is silicon oxide or silicon nitride.

21. The support of claim 18, wherein the insulating layer has a thickness in the range of about 10 nm to 3 μm.

22. An electronic structure comprising a support according to claim 15, and at least one layer of a nitride material in which at least one electronic component is formed.

23. The structure of claim 22, wherein the nitride material is gallium nitride, aluminum nitride, indium nitride or gallium-indium nitride, or a compound of gallium nitride and aluminum nitride.

24. A method for facilitating epitaxial growth of a layer of a nitride material, which comprises providing a layer of an insulating monocrystalline carbide or nitride on a substrate formed from a polycrystalline ceramic material having thermal conductivity of at least 1.5 W.cm⁻¹.K⁻¹ so that the nitride layer can be epitaxially grown thereon.

25. The method of claim 24, which further comprises epitaxially growing a layer of gallium nitride, aluminum nitride, indium nitride, gallium-indium nitride, or a compound of gallium nitride and aluminum nitride on the insulating layer.

26. The method of claim 25, which further comprises forming an active conducting layer on the epitaxially grown layer.

27. The method of claim 26, which further comprises etching the active layer to form at least one electronic component.

28. The method of claim 27, wherein the electronic component comprises an inductor, capacitor, transmission line, or transistor.
